(19) United States
(12) Patent Application Publication
(10) Pub. No.: US 2022/0367765 A1
(43) Pub. Date: Nov. 17, 2022

(54) DISPLAY MODULE AND ELECTRONIC DEVICE INCLUDING THE SAME

(71) Applicant: SAMSUNG ELECTRONICS CO., LTD., Suwon-si (KR)

(72) Inventors: Keunsik LEE, Suwon-si Gyeonggi-do (KR); Hakyeol KIM, Suwon-si Gyeonggi-do (KR); Jaewook PARK, Suwon-si Gyeonggi-do (KR); Jungwoon SHIN, Suwon-si Gyeonggi-do (KR)

(21) Appl. No.: 17/840,019

(22) Filed: Jun. 14, 2022

Related U.S. Application Data
(63) Continuation of application No. PCT/KR2022/005346, filed on Apr. 13, 2022.

(30) Foreign Application Priority Data
May 17, 2021 (KR) 10-2021-0063224

(51) Int. Cl. H01L 33/50; H01L 27/15; H01L 33/54

(52) U.S. Cl. CPC H01L 33/505; H01L 27/156; H01L 33/54

(57) ABSTRACT

A display module in which a plurality of pixels are arranged and an electronic device including the display module are disclosed. The display module includes: a display panel including a substrate, a plurality of light emitting elements mounted on the substrate, a bank portion disposed on the substrate to space the plurality of light emitting elements apart from each other, color conversion layers disposed in cells defined by the bank portion to cover the light emitting elements, and an encapsulation layer covering the bank portion and the color conversion layers, and a driving circuit disposed on the substrate and configured to generate a driving signal of the plurality of light emitting elements, the bank portion including a first layer having a thickness less than a height of an active layer of the light emitting element, and a second layer disposed on the first layer, spaced apart from a side surface of the light emitting element, and configured to reflect light emitted from the side surface of the light emitting element.

### CROSS-REFERENCE TO RELATED APPLICATIONS

This application is a continuation of International Application No. PCT/KR2022/005346 designating the United States, filed on Apr. 13, 2022, in the Korean Intellectual Property Receiving Office and claiming priority to Korean Patent Application No. 10-2021-0063224, filed on May 17, 2021, in the Korean Intellectual Property Office, the disclosures of which are incorporated by reference herein in their entireties.

### BACKGROUND

### Field

The disclosure relates to a display module and an electronic device including the same, and for example, relates to a display module including a color conversion material which emits light of a specified color by excitation by light emitted from a light emitting element and an electronic device including thereof.

### Description of Related Art

A display module and an electronic device (e.g., display device) including the display module use a structure capable of lighting by joining on a substrate that is a backplane on which a driving circuit is formed. In recent years, research for enhancing color reproducibility and power consumption by applying a light emitting element which emits blue light with advantageous light emitting efficiency and a color conversion layer to the display device is being carried out.

The color conversion layer may refer, for example, to an element configuring a pixel or a sub-pixel of the display device and emits light converted into one of red, green, or blue light by incident light emitted from a light source of the display device. The display device may display a color image through the pixel including the color conversion layer.

### SUMMARY

Embodiments of the disclosure may provide a display module capable of maximizing and/or improving light efficiency and enhancing a contrast ratio using side light of a light emitting element and an electronic device including the same.

In accordance with various example embodiments of the disclosure, there is provided a display module including: a display panel including a substrate, a plurality of light emitting elements mounted on the substrate, a bank portion disposed on the substrate to space the plurality of light emitting elements apart from each other, color conversion layers filled or disposed in cells defined by the bank portion and covering the light emitting elements, and an encapsulation layer covering the bank portion and the color conversion layers; and a driving circuit disposed on the substrate and configured to generate a driving signal of the plurality of light emitting elements, wherein the bank portion includes: a first layer having a thickness less than a thickness of an active layer of the light emitting element; and a second layer laminated or disposed on the first layer, spaced apart from a side surface of the light emitting element, and configured to reflect light emitted from the side surface of the light emitting element.

In accordance with various example embodiments of the disclosure, there is provided a display module including: a display panel including a substrate, a plurality of light emitting elements mounted on the substrate, a bank portion disposed on the substrate to space the plurality of light emitting elements apart from each other, color conversion layers filled or disposed in cells defined by the bank portion and covering the light emitting elements, and a color filter layer covering the bank portion and the color conversion layer; and a driving circuit disposed on the substrate and configured to generate a driving signal of the plurality of light emitting elements, wherein the bank portion includes: a first layer having a thickness less than a thickness of an active layer of the light emitting element; and a second layer laminated or disposed on the first layer, spaced apart from a side surface of the light emitting element, and configured to reflect light emitted from the side surface of the light emitting element, and the color filter layer includes color filters for different colors, a transmission layer, and a black matrix corresponding to a pattern of the bank portion.

In accordance with various example embodiments of the disclosure, there is provided an electronic device including a display module including: a display panel including a substrate, a plurality of light emitting elements mounted on the substrate, a bank portion disposed on the substrate to space the plurality of light emitting elements apart from each other, color conversion layers filled or disposed in cells partitioned by the bank portion and covering the light emitting elements, and an encapsulation layer covering the bank portion and the color conversion layers, and a driving circuit disposed on the substrate and configured to generate a driving signal of the plurality of light emitting elements, and a processor configured to control the driving circuit to generate a driving signal for controlling light emission of the plurality of light emitting elements, in which the bank portion is laminated or disposed as at least two layers and includes: a first layer having a thickness less than a thickness of an active layer of the light emitting element; and a second layer laminated or disposed on the first layer, spaced apart from a side surface of the light emitting element, and configured to reflect light emitted from the side surface of the light emitting element.

According to various example embodiments of the disclosure, it is possible to minimize and/or reduce optical interference between adjacent pixels in a high-definition mobile display thereby enhancing image quality.

According to various example embodiments of the disclosure, it is possible to maximize and/or improve the amount of light emitted from the light emitting element using side light of the light emitting element thereby enhancing light efficiency.

In addition, through this disclosure, various effects that are directly or indirectly realized may be provided.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a display module of the electronic device according to various embodiments;

FIG. 3 is a diagram illustrating an example display panel according to various embodiments;

FIG. 4 is an enlarged diagram of a part IV illustrated in FIG. 3 which illustrates a pixel structure of the display panel according to various embodiments;

FIG. 5A is a diagram illustrating an example arrangement different from the arrangement of sub-pixels illustrated in FIG. 4 according to various embodiments;

FIG. 5B is a diagram illustrating an example arrangement different from arrangement of sub-pixels illustrated in FIG. 4 according to various embodiments;

FIG. 5C is a diagram illustrating an example arrangement different from the arrangement of sub-pixels illustrated in FIG. 4 according to various embodiments;

FIG. 6 is a cross-sectional view illustrating an example pixel structure of the display panel according to various embodiments;

FIG. 7 is an enlarged diagram illustrating a first sub-pixel illustrated in FIG. 6 according to various embodiments;

FIG. 8 is a cross-sectional view illustrating an example pixel structure of a display panel according to various embodiments;

FIG. 9 is a cross-sectional view illustrating an example pixel structure of a display panel according to various embodiments;

FIG. 10 is a cross-sectional view illustrating an example pixel structure of a display panel according to various embodiments;

FIG. 11 is a cross-sectional view illustrating an example pixel structure of a display panel according to various embodiments;

FIG. 12 is a cross-sectional view illustrating an example pixel structure of a display panel according to various embodiments;

FIG. 13 is a cross-sectional view illustrating an example pixel structure of a display panel according to various embodiments;

FIG. 14 is a cross-sectional view illustrating an example pixel structure of a display panel according to various embodiments; and

FIG. 15 is a cross-sectional view illustrating an example pixel structure of a display panel according to various embodiments.

### DETAILED DESCRIPTION

The disclosure will be described in greater detail below after briefly explaining the terms used in the disclosure. In describing the disclosure, a detailed description of the related art may be omitted and overlapping descriptions of the same configuration may be omitted.

The terms used in embodiments of the disclosure have been selected as widely used general terms as possible in consideration of functions in the disclosure, but these may vary in accordance with the intention of those skilled in the art, the precedent, the emergence of new technologies and the like. In addition, in a certain case, there may also be an arbitrarily selected term, in which case the meaning will be described in the description of the disclosure. Therefore, the terms used in the disclosure should be defined based on the meanings of the terms themselves and the contents throughout the disclosure, rather than the simple names of the terms.

The embodiments of the disclosure may be variously changed and include various embodiments, and specific embodiments will be shown in the drawings and described in detail in the description. However, it should be understood that this is not to limit the scope of the specific embodiments and all modifications, equivalents, and/or alternatives included in the disclosed spirit and technical scope are included. In describing the disclosure, a detailed description of the related art may be omitted when it is determined that the detailed description may unnecessarily obscure a gist of the disclosure.

The terms “first”, “second”, “third”, or the like may be used for describing various elements but the elements may not be limited by the terms. The terms are used simply to distinguish one element from another. For example, a first element may be referred to as a second element and the second element may also be similarly referred to as the first element, while not departing from the scope of a right of the disclosure.

Unless otherwise defined specifically, a singular expression may encompass a plural expression. It is to be understood that the terms such as “comprise” or “consist of” are used herein to designate a presence of characteristic, number, step, operation, element, part, or a combination thereof, and not to preclude a presence or a possibility of adding one or more of other characteristics, numbers, steps, operations, elements, parts or a combination thereof.

A term such as “module” or a “unit” in the disclosure may perform at least one function or operation, and may be implemented as hardware, software, or a combination of hardware and software. Further, except for when each of a plurality of “modules”, “units”, and the like needs to be realized in an individual hardware, the components may be integrated in at least one module and be implemented in at least one processor.

Hereinafter, with reference to the accompanying drawings, embodiments of the disclosure will be described in greater detail. But, the disclosure may be implemented in various different forms and is not limited to the embodiments described herein. In addition, in the drawings, the parts not relating to the description may be omitted for clearly describing the disclosure, and the same reference numerals are used for the same parts throughout the disclosure.

In addition, hereinafter, various example embodiments of the disclosure will be described in greater detail with reference to the accompanying drawings and content illustrated in the accompanying drawings, but the disclosure is not limited to the illustrated embodiments.

Hereinafter, a display module and an electronic device including the same according to various embodiments of the disclosure will be described in greater detail.

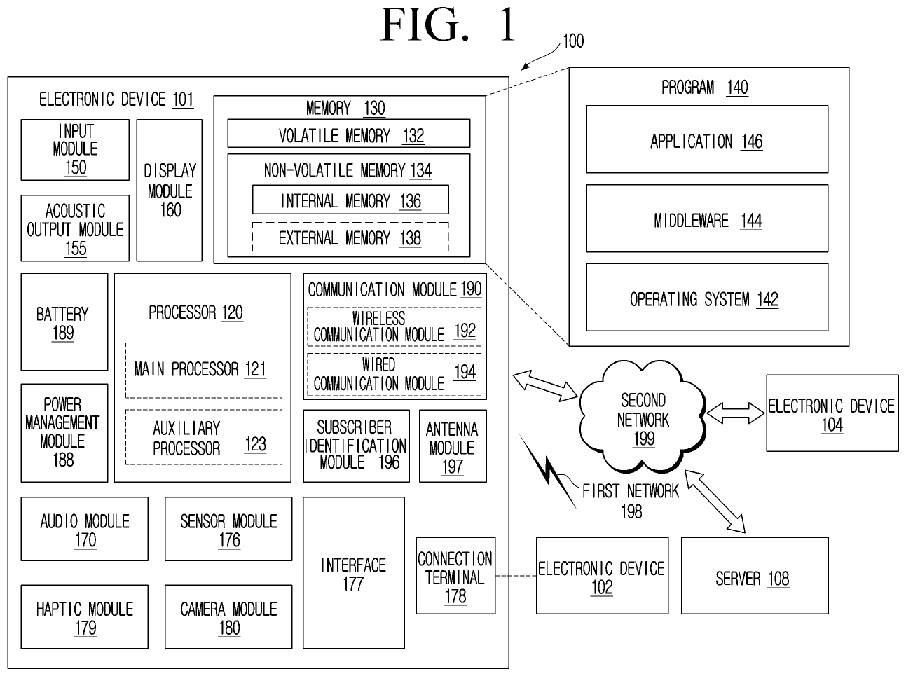

FIG. 1 is a block diagram illustrating an example electronic device in a network environment according to various embodiments.

FIG. 1 is a block diagram of an electronic device 101 in a network environment 100 according to various embodiments. Hereinafter, for convenience of description, a machine according to various embodiments of the disclosure may be collectively referred to as the “electronic device”, but the machine of the various embodiments may be any electronic device, including, for example, and without limitation, a wireless communication device, a display device, a portable communication device, or the like.

Referring to FIG. 1, in the network environment 100, the electronic device 101 may communicate with an electronic device 102 through a first network 198 (e.g., short-range wireless communication network) or communicate with at least one of an electronic device 104 or a server 108 through a second network 199 (e.g., long-distance wireless communication network). According to an embodiment, the electronic device 101 may communicate with the electronic device 104 through the server 108. According to an embodiment, the electronic device 101 may include a processor 120, a memory 130, an input module 150, an acoustic output module 155, a display module 160, an audio module 170, a sensor module 176, an interface 177, a connection terminal 178, a haptic module 179, a camera module 180, a power management module 188, a battery 189, a communication module 190, a subscriber identification module (SIM) 196, or an antenna module 197. In various embodiments, in the electronic device 101, at least one (e.g., connection terminal 178) among the above elements may be omitted or one or more other elements may be added. In various embodiments, some of the elements (e.g., sensor module 176, camera module 180, or antenna module 197) may be combined into one element (e.g., display module 160).

According to an embodiment, the processor 120 may execute software (e.g., program 140) to control at least one of other elements (e.g., hardware or software element) of the electronic device 101 connected to the processor 120 and perform various data processing or operations. According to an embodiment, as at least a part of the data processing or operation, the processor 120 may store a command or data received from other elements (e.g., sensor module 176 or communication module 190) in a volatile memory 132, process the command or data stored in the volatile memory 132, and store the result data in a non-volatile memory 134. According to an embodiment, the processor 120 may include a main processor 121 (e.g., a central processing unit or an application processor) or an auxiliary processor 123 capable of being operated independently therefrom or along therewith (e.g., graphics processing unit, neural processing unit (NPU), image signal processor, sensor hub processor, or communication processor). For example, when the electronic device 101 includes the main processor 121 and the auxiliary processor 123, the auxiliary processor 123 may use lower energy than the main processor 121 or may be set to be specialized in a designated function. The auxiliary processor 123 may be implemented to be separated from the main processor 121 or as a part thereof.

According to an embodiment, the auxiliary processor 123 may control at least some of function or states related to at least one element (e.g., display module 160, sensor module 176, or communication module 190) of the elements of the electronic device 101, replacing the main processor 121 while the main processor 121 is in an inactive (e.g., sleep) state or along with the main processor 121 while the main processor 121 is in an active (e.g., application execution) state. According to an embodiment, the auxiliary processor 123 (e.g., image signal processor or communication processor) may be implemented as a part of another functionally related element (e.g., camera module 180 or communication module 190). According to an embodiment, the auxiliary processor 123 (e.g., neural network processing device) may include a hardware structure specialized in processing of an artificial intelligence model. The artificial intelligence model may be generated through machine learning. Such learning may be performed in the electronic device 101 itself which the artificial intelligence model works, or may also be performed through a separate server (e.g., server 108). Examples of the learning algorithm include supervised learning, unsupervised learning, semi-supervised learning, or reinforcement learning, but the learning algorithm of the disclosure is not limited to the above examples. The artificial intelligence model may include a plurality of artificial neural network layers. The artificial neural network may be a deep neural network (DNN), a convolutional neural network (CNN), recurrent neural network (RNN), restricted Boltzmann machine (RBM), deep belief network (DBN), bidirectional recurrent deep neural network (BRDNN), or deep Q-network, or one of two or more combinations thereof, but there is no limitation to these examples. The artificial intelligence model may include a software structure additionally or alternatively, in addition to the hardware structure.

According to an embodiment, the processor 120 may control general operations of the electronic device 101. The processor 120 may be configured with one or a plurality of processors. For example, the processor 120 may perform operations of the electronic device 101 according to various embodiments of the disclosure by executing at least one instruction stored in the memory.

According to an embodiment, the processor 120 may transfer pieces of information to each module and then may be turned into an inactive state. The processor 120 may be in the inactive state in an always-on-display (AOD) mode. The processor 120 may maintain the inactive state in the AOD mode, may be activated to transfer information, in a case of transferring image information and/or control information to a display driver IC 230, a touch sensor IC 253, a pressure sensor IC (not illustrated), or the like, and then may be turned into the inactive state again.

According to an embodiment, the processor 120 may be implemented as, for example, and without limitation, a digital signal processor, a microprocessor, a graphics processing unit (GPU), an artificial intelligence (AI) processor, a neural processing unit (NPU), and a time controller (TCON) for processing digital image signals. However, there is no limitation thereto, and the processor may include one or more of a central processing unit (CPU), a dedicated processor, a microcontroller unit (MCU), a microprocessing unit (MPU), a controller, an application processor (AP), or a communication processor (CP), and an ARM processor or may be defined as the corresponding term. In addition, the processor 120 may be implemented as System on Chip (SoC) or large scale integration (LSI) including the processing algorithm or may be implemented in form of an application specific integrated circuit (ASIC) or a field programmable gate array (FPGA).

According to an embodiment, the processor 120 may operate an operating system or an application program to control hardware or software elements connected to the processor 120 and perform various data processing and operations. In addition, the processor 120 may load and process a command or data received from at least one of other elements on a volatile memory and store various pieces of data in a non-volatile memory.

According to an embodiment, the memory 130 may store various pieces of data used by at least one element (e.g., processor 120 or sensor module 176) of the electronic device 101. The data may include, for example, software (e.g., program 140) and input data or output data for a command related thereto. The memory 130 may include the volatile memory 132 or the non-volatile memory 134.

According to an embodiment, the processor 120 may be stored in the memory 130 as the software and may include, for example, an operating system 142, a middleware 144, or an application 146.

According to an embodiment, the input module 150 may receive a command or data to be used by the element (e.g., processor 120) of the electronic device 101 from the outside (e.g., user) of the electronic device 101. The input module 150 may include, for example, a microphone, a mouse, a keyboard, a key (e.g., button), or a digital pen (e.g., stylus pen).

According to an embodiment, the acoustic output module 155 may output an acoustic signal to the outside of the electronic device 101. The acoustic output module 155 may include, for example, a speaker or a receiver. The speaker may be used for general purpose such as multimedia reproduction or recording reproduction. The receiver may be used to receive a phone call. According to an embodiment, the receiver may be implemented to be separated from the speaker or as a part thereof.

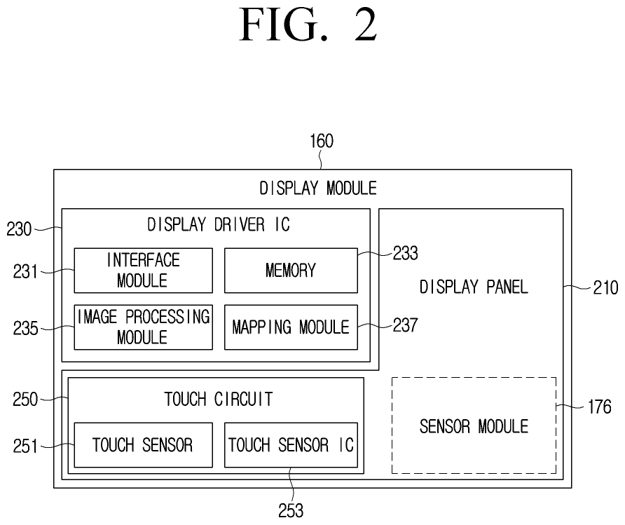

According to an embodiment, the display module 160 may visually provide information to the outside (e.g., user) of the electronic device 101. The display module 160 may include, for example, a display, a hologram device, or a projector, and a control circuit for controlling the corresponding device. According to an embodiment, the display module 160 may include a touch sensor 251 set to detect a touch and may include a pressure sensor set to measure a strength of a force generated by the touch. A specific structure of the display module 160 will be described in detail with reference to FIG. 2.

According to an embodiment, the audio module 170 may convert a sound into an electrical signal or convert an electrical signal into a sound. According to an embodiment, the audio module 170 may obtain a sound through the input module 150 or output a sound through the acoustic output module 155 or an external electronic device (e.g., electronic device 102 (e.g., speaker or headphones)) connected directly or wirelessly to the electronic device 101.

According to an embodiment, the sensor module 176 may detect an operation state (e.g., power or temperature) of the electronic device 101 or an external environment state (e.g., user state) and generate an electrical signal or a data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biological sensor, a temperature sensor, a humidity sensor, or an illumination sensor.

According to an embodiment, the interface 177 may support one or more designated protocols that can be used for the electronic device 101 to be directly or wirelessly connected to an external electronic device (e.g., electronic device 102). According to an embodiment, the interface 177 may include, for example, a high definition multimedia interface (HDMI), a universal serial bus (USB) interface, an SD card interface, or an audio interface.

According to an embodiment, the connection terminal 178 may include a connector through which the electronic device 101 is able to be physically connected to the external electronic device (e.g., electronic device 102). According to an embodiment, the connection terminal 178 may include, for example, an HDMI connector, a USB connector, an SD card connector, or an audio connector (e.g., headphone connector).

According to an embodiment, the haptic module 179 may convert an electrical signal into a mechanical stimulus (e.g., vibration or movement) or electrical stimulus that the user is able to recognize through haptic or movement sense. According to an embodiment, the haptic module 179 may include, for example, a motor, a piezoelectric element, or an electrical stimulation device.

According to an embodiment, the camera module 180 may capture a still image or a video. According to an embodiment, the camera module 180 may include one or more lenses, image sensors, image signal processors, or flashes.

According to an embodiment, the power management module 188 may manage a power supplied to the electronic device 101. According to an embodiment, the power management module 188 may be implemented, for example, as at least a part of a power management integrated circuit (PMIC).

According to an embodiment, the battery 189 may supply the power to at least one element of the electronic device 101. According to an embodiment, the battery 189 may include, for example, a non-rechargeable primary battery, a rechargeable secondary battery, or a fuel cell.

According to an embodiment, the communication module 190 may support establishment of a direct (e.g., wired) communication channel or a wireless communication channel between the electronic device 101 and the external electronic device (e.g., electronic device 102, electronic device 104, or server 108), and communication through the established communication channel. The communication module 190 may be operated independently from the processor 120 (e.g., application processor) and may include one or more communication processor supporting the direct (e.g., wired) communication or wireless communication. According to an embodiment, the communication module 190 may include a wireless communication module 192 (e.g., cellular communication module, short-range wireless communication module, or global navigation satellite system (GNSS) communication module) or a wired communication module 194 (e.g., local area network (LAN) communication module or power line communication module). The corresponding communication module among these communication modules may communicate with the external electronic device 104 through the first network 198 (e.g., short-range communication network such as Bluetooth, wireless fidelity (WiFi) direct, or infrared data association (IrDA)) or the second network 199 (e.g., long-distance communication network such as legacy cellular network, 5G network, next-generation communication network, the Internet, or computer network (e.g., LAN or WAN))]. Various types of communication modules may be combined into one element (e.g., single chip) or implemented as a plurality of elements separated from each other (e.g., plurality of chips). The wireless communication module 192 may confirm or authenticate the electronic device 101 in the communication network such as the first network 198 or the second network 199 using subscriber information (e.g., international mobile subscriber identity (IMSI)) stored in the subscriber identification module 196.

According to an embodiment, the wireless communication module 192 may support 5G network after the 4G network and next-generation communication technology, for example, new radio (NR) access technology. The NR access technology may support high-speed transmission of high-capacity data (enhanced mobile broadband (eMBB)), terminal power minimization and access of a plurality of terminals (massive machine type communications (mMTC)), or ultra-reliable and low-latency communications (URLLC). The wireless communication module 192 may support, for example, radio frequency band (e.g., mmWave band) to achieve high data transmission rate. The wireless communication module 192 may support various technologies for ensuring performance in the radio frequency band, for example, beamforming, massive multiple-input and multiple-output (MIMO), full dimensional MIMO (FD-MIMO), array antenna, analog beam-forming, or large scale antenna, and the like. The wireless communication module 192 may support various requirements regulated in the electronic device 101, the external electronic device (e.g., electronic device 104), or network system (e.g., second network 199). According to an embodiment, the wireless communication module 192 may support a peak data rate for implementing eMBB (e.g., 20 Gbps or more), loss coverage for implementing mMTC (e.g., 164 dB or less), or U-plane latency for implementing URLLC (e.g., each of downlink (DL) or uplink (UL) of 0.5 ms or less or round trip of 1 ms or less).

According to an embodiment, the antenna module 197 may transmit a signal or power to the outside (e.g., external electronic device) or receive a signal or power from the outside. According to an embodiment, the antenna module 197 may include a plurality of antennas (e.g., array antenna), and at least one antenna suitable for a communication system used in a communication network such as the first network 198 or the second network 199 may be selected from the plurality of antennas by the communication module 190.

According to an embodiment, the antenna module 197 may include a plurality of antennas (e.g., array antenna), and according to another embodiment, the antenna module 197 may include an antenna including a conductor formed on a substrate (e.g., PCB) or a radiator formed in a conductive pattern.

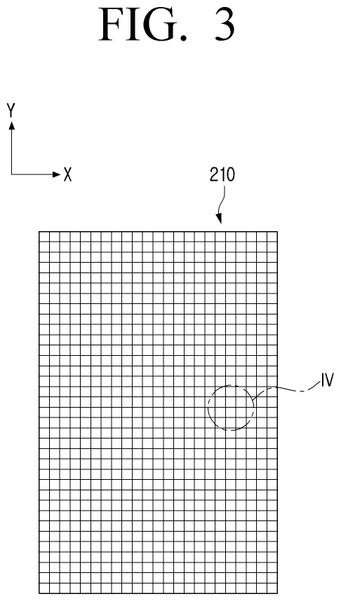

According to various embodiments, the antenna module 197 may form an mmWave antenna module. According to an embodiment, the mmWave antenna module may include a print circuit board, an RFIC which is disposed on a first surface (e.g., lower surface) of the print circuit board or to be adjacent thereto and supports a designated radio frequency band (e.g., mmWave band), and a plurality of antennas (e.g., array antenna) which are disposed on a second surface (e.g., upper surface or side surface) of the print circuit board or to be adjacent thereto and transmit or receive a signal in the designated radio frequency band. The specific structure of the antenna module 197 according to various embodiments of the disclosure will be described in detail with reference to FIG. 3 and subsequent drawings.

The signal or the power may be transmitted or received between the communication module 190 and the external electronic device through at least one antenna. According to some embodiments, other components (e.g., radio frequency integrated circuit (RFIC)) other than the radiator may be additionally formed as a part of the antenna module 197.

At least some of the above elements may be connected to each other through communication method between peripheral machines (e.g., bus, general purpose input and output (GPIO), a serial peripheral interface (SPI), or a mobile industry processor interface (MIPI) and may exchange a signal (e.g., command or data) therebetween.

The command or data may be transmitted or received between the electronic device 101 and the external electronic device 104 through the server 108 connected to the second network 199. Each of the external electronic devices 102 and 104 may be the same type or different type of device from the electronic device 101. According to an embodiment, all or some operations executed on the electronic device 101 may be executed on one or more external electronic devices of the external electronic devices 102, 104, and 108. For example, in a case where the electronic device 101 needs to perform a certain function or service automatically or in response to a request from a user or another device, the electronic device 101 may request one or more external electronic devices to perform at least a part of the function or the service, instead of executing the function or service autonomously or in addition thereto. The one or more external electronic devices which have received the above request may execute at least the part of the requested function or the service or additional function or service related to the above request, and transfer the result of the execution to the electronic device 101. The electronic device 101 may process the result as it is or additionally and provide the result as at least a part of the response to the request. For this, for example, cloud computing, dispersion computing, mobile edge computing (MEC), or client-server computing technology may be used. The electronic device 101 may provide, for example, ultra-low-latency service using the dispersion computing or the mobile edge computing. According to another embodiment, the external electronic device 104 may include Internet of Things (IoT). The server 108 may be an intelligent server using machine learning and/or a neural network. According to an embodiment, the external electronic device 104 or the server 108 may be included in the second network 199. The electronic device 101 may be applied to an intelligent service based on the 5G communication technology and IoT related technology (e.g., smart home, smart city, smart car, or health care).

FIG. 2 is a block diagram illustrating an example configuration of a display module of the electronic device according to various embodiments.

Referring to FIG. 2, the display module 160 may include a display panel 210 and a display driver IC (DDI) 230 for controlling the display panel.

The display driver IC 230 may include an interface module 231, a memory 233 (e.g., buffer memory), an image processing module 235, and/or a mapping module 237. Each of the various modules may include various processing circuitry and/or executable program instructions. The display driver IC 230 may receive, for example, image information including image data and an image control signal corresponding to a command for controlling the image data from another element of the electronic device 101 through the interface module 231. For example, according to an embodiment, the image information may be received from the processor 120 (e.g., main processor 121 (e.g., application processor) or the auxiliary processor 123 operated independently from the function of the main processor 121 (e.g., graphics processing unit)).

The display driver IC 230 may communicate with a touch circuit 250 or a sensor module 176 through the interface module 231. In addition, the display driver IC 230 may store at least some of the received image information in the memory 233, for example, in a frame unit. For example, the image processing module 235 may perform preprocessing or post-processing (e.g., resolution, brightness, or size adjustment) of at least some of the above image data based on at least a feature of the image data or a feature of the display panel 210. The mapping module 237 may generate a voltage value or a current value corresponding to the image data that is preprocessed or post-processed through the image processing module 135. According to an embodiment, the generation of the voltage value or the current value may be performed, for example, based on at least a part of an attribute of pixels (e.g., arrangement of pixels (RGB strip or PenTile structure) or size of each of the sub-pixels) of the display panel 210. Since at least some pixels of the display panel 210 are, for example, driven based on at least a part of the voltage value or the current value, visual information (e.g., text, image, or icon) corresponding to the image data may be displayed through the display panel 210.

According to an embodiment, the display module 160 may further include the touch circuit 250. The touch circuit 250 may include the touch sensor 251 and the touch sensor IC 253 for controlling the touch sensor. For example, the touch sensor IC 253 may control the touch sensor 251 to detect a touch input or a hovering input on a designated location of the display panel 210. For example, the touch sensor IC 253 may detect the touch input or the hovering input by measuring a change of a signal (e.g., voltage, amount of light, resistance, or charge amount) on the designated location of the display panel 210. The touch sensor IC 253 may provide the information on the detected touch input or the hovering input (e.g., location, area, pressure, or time) to the processor 120. According to an embodiment, at least a part of the touch circuit 250 (e.g., touch sensor IC 253) may be included as a part of the display driver IC 230 or the display panel 210, or as a part of another element (e.g., auxiliary processor 123) disposed outside of the display module 160.

According to an embodiment, the display module 160 may further include at least one sensor (e.g., fingerprint sensor, iris sensor, pressure sensor, or illumination sensor) of the sensor module 176 or a control circuit thereof. In this case, the at least one sensor or the control circuit thereof may be embedded in a part of the display module 160 (e.g., display panel 210 or display driver IC 230) or a part of the touch circuit 250. For example, if the sensor module 176 embedded in the display module 160 includes a biological sensor (e.g., fingerprint sensor), the biological sensor may obtain biological information (e.g., fingerprint image) related to the touch input through some areas of the display panel 210. In another example, if the sensor module 176 embedded in the display module 160 includes the pressure sensor, the pressure sensor may obtain pressure information related to the touch input through some or the entire area of the display panel 210. According to an embodiment, the touch sensor 251 or the sensor module 176 may be disposed between pixels of a pixel layer of the display panel 210 or above or below the pixel layer.

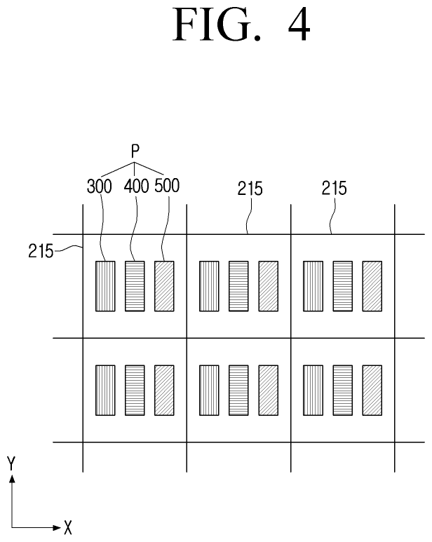

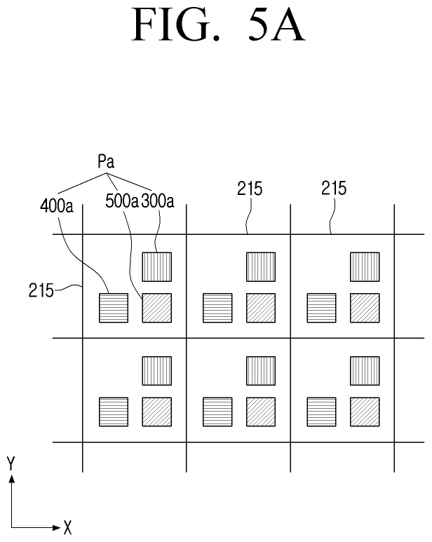

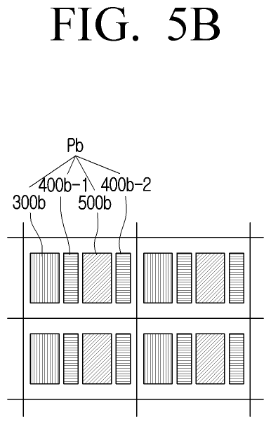

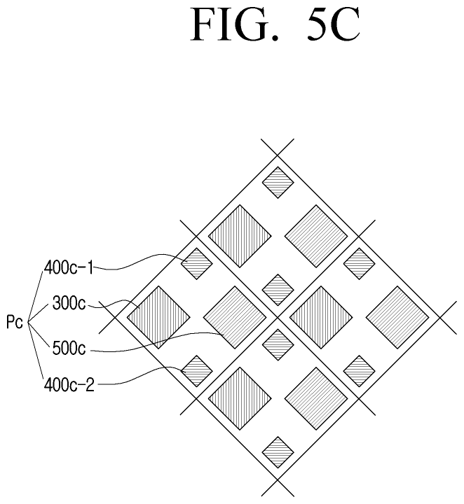

FIG. 3 is a diagram illustrating an example display panel of the electronic device according to various embodiments, FIG. 4 is an enlarged diagram of a part IV illustrated in FIG. 3 which illustrates a pixel structure of the display panel according to various embodiments, FIG. 4 is a diagram illustrating arrangement different from arrangement of sub-pixels illustrated in FIG. 3, and FIGS. 5A, 5B and 5C are diagrams illustrating example pixel arrangements different from arrangement of sub-pixels illustrated in FIG. 4 according to various embodiments.

The electronic device according to an embodiment of the disclosure (e.g., electronic device 101 of FIG. 1) may be configured in a single unit or may be installed and applied to electronic goods or machines such as a wearable device, a portable device, a handheld device, various mobile devices or wireless communication devices that need to include a display. In addition, the electronic device 101 of an embodiment may be implemented as a TV or may be applied without limitation, as long as it is a device with a display function such as, for example, and without limitation, a video wall, a large format display (LFD), a digital signature, a digital information display (DID), a projector display, or the like.

In addition, the electronic device 101 according to an embodiment of the disclosure may also be applied to various display devices such as, for example, and without limitation, a monitor for a personal computer (PC), high-definition TV and signage (or digital signage), or an electronic display through a plurality of assembly arrangements in which a plurality of display modules (e.g., display module 160 of FIGS. 1 and 2) in a matrix type, etc.

Referring to FIGS. 3 and 4, the display panel 210 may include a plurality of pixel areas 215 disposed in a matrix form. In each pixel area 215, one pixel P may be disposed, and the one pixel P may include, for example, and without limitation, a first sub-pixel 300 which emits red (R) light, a second sub-pixel 400 which emits green (G) light, and a third sub-pixel 500 which emits blue (B) light.

In an area of one pixel area 215 which is not occupied by the first to third sub-pixels 300, 400, and 500, a plurality of thin film transistors (TFT) for driving the first to third sub-pixels 300, 400, and 500 may be disposed.

In the disclosure, the example in which the first to third sub-pixels 300, 400, and 500 are disposed in the one pixel area 215 in a row as illustrated in FIG. 4, but there is no limitation thereto. For example, referring to FIG. 5A, in the one pixel area 215, one pixel Pa is disposed, and one pixel Pa may be disposed in various forms such that first to third sub-pixels 300a, 400a, and 500a are disposed in a form of horizontally-flipped L.

Referring to FIGS. 5B and 5C, a plurality of pixels may be arranged in a pentile RGBG method. The pentile RGBG method may refer, for example, to a method for arranging the number of the red, green, and blue sub-pixels in a ratio of 1:2:1 (RGBG) due to the human eye recognizing blue less accurately and recognizing green most easily. The pentile RGBG method is effective, since it increases a yield rate, reduces unit cost, and realizes high resolution of a small screen. In the pentile RGBG method, for example, referring to FIG. 5B, one pixel Pb may include four sub-pixels 300b, 400b-1, 400b-2, and 500b. In this case, the red sub-pixel 300b and the blue sub-pixel 500b have the same or substantially similar sizes, and the first and second green sub-pixels 400b-1 and 400b-2 may be formed with a size smaller than that of the red sub-pixel 300b and the blue sub-pixel 500b. The arrangement of sub-pixels in the one pixel Pb may be disposed, for example, in the order of the red sub-pixel 300b, the first green sub-pixel 400b-1, the blue sub-pixel 500b, and the second green sub-pixel 400b-2. In the pentile RGBG method, referring to FIG. 5C, one pixel Pc may include four sub-pixels 300c, 400c-1, 400c-2, and 500c. The first and second green sub-pixels 400c-1 and 400c-2 may be disposed with vertical symmetry between the red sub-pixel 300c and the blue sub-pixel 500c.

In the disclosure, the display panel 210 may be implemented as, for example, and without limitation, a touch screen combined with a touch sensor, a flexible display, a rollable display, a 3D display, and/or a display to which a plurality of display modules are physically connected.

The electronic device 101 according to an embodiment of the disclosure (see FIG. 1) may display various images. The image may include a still image and/or video, and the electronic device 101 may display various images such as broadcasting contents, multimedia contents, and the like. In addition, the electronic device 101 may display a user interface UI and an icon. For example, the display module 160 (see FIG. 1) may include the display driver IC 230 (see FIG. 2), and the display driver IC 230 may display an image based on an image signal received from the processor 120 (see FIG. 1). In an example, the display driver IC 230 may generate a driving signal of the plurality of sub-pixels based on the image signal received from the processor 120 and display an image by controlling light emission of the plurality of sub-pixels based on the driving signal.

The display panel 210 according to an embodiment of the disclosure may include a substrate capable of being implemented in a form of, for example, and without limitation, amorphous silicon (a-Si) TFT, low temperature polycrystalline silicon (LTPS) TFT, low temperature polycrystalline oxide (LTPO) TFT, hybrid oxide and polycrystalline silicon (HOP) TFT, liquid crystalline polymer (LCP) TFT, organic TFT (OTFT), or the like.

According to an embodiment, the display driver IC 230 may transmit the driving signal (e.g., driver driving signal, gate driving signal, or the like) to the display based on the image information received from the processor 120. The display driver IC 230 may display various pieces of information (e.g., current time, message receiving state, and the like) with the operation of the processor 120 by itself in the sleep mode.

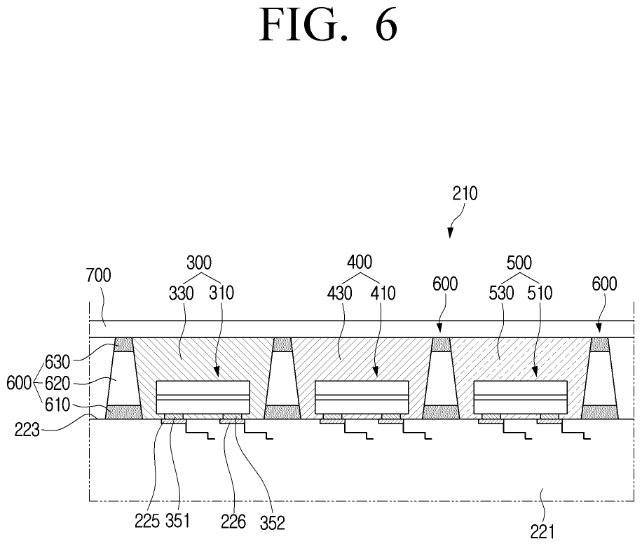

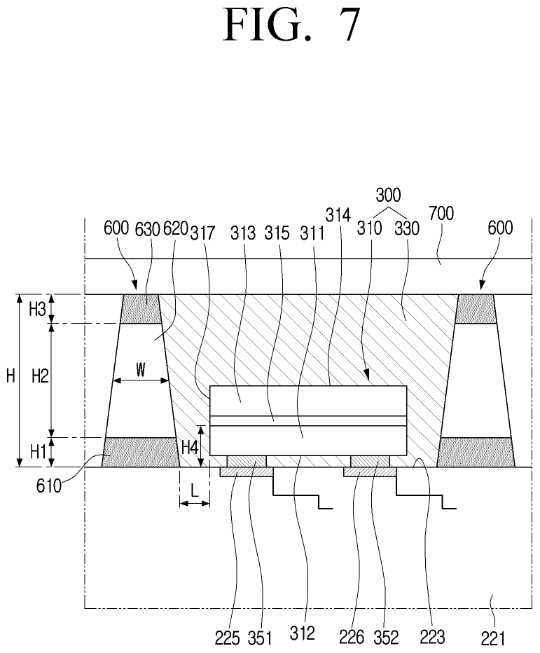

FIG. 6 is a cross-sectional view illustrating an example pixel structure of the display panel according to various embodiments, and FIG. 7 is an enlarged diagram illustrating a first sub-pixel illustrated in FIG. 6 according to various embodiments.

Referring to FIGS. 6 and 7, the display panel (e.g., display panel 210 of FIG. 2) may include a substrate 221 and a plurality of pixels mounted on the substrate 221. Each pixel may include two sub-pixels which emit different colors, and in the disclosure, it is described that one pixel is formed of three sub-pixels which emit red, green, and blue lights.

According to an embodiment, the substrate 221 may be formed of a transparent glass material (main component is SiO₂), but is not limited thereto and may be formed of a transparent or translucent polymer. In this case, the polymer may be an insulating organic material such as, for example, and without limitation, polyethersulfone (PES), polyimide (PI), polyethylene terephthalate (PET), polyethylene naphthalate (PEN), polycarbonate (PC), or the like.

According to an embodiment, for the substrate 221, a plurality of TFT (not illustrated) may be provided. In the disclosure, the TFT is not limited in specific structure or type. For example, the TFT in this disclosure may be implemented, for example, and without limitation, as LTPS TFT, Oxide TFT, a-Si TFT (a-silicon TFT), organic TFT (OTFT), graphene TFT, or the like.

According to an embodiment, a bank portion 600 formed with multiple layers (e.g., at least two layers) may be disposed on the substrate 221. The bank portion 600 may form (or define) a plurality of cells, for example, as it is formed in lattice arrangement. In the disclosure, a cell provided on the substrate 221 by the bank portion 600 may correspond to a pixel area (e.g., pixel area 215 of FIGS. 4 and 5A). According to an embodiment, the bank portion 600 may be formed with multiple layers. For example, the bank portion 600 may include a first layer 610 disposed on an upper surface 223 of the substrate 221, a second layer 620 that is formed on an upper portion of the first layer 610 and formed of a material different from the first layer 610, and a third layer 630 that is formed on an upper portion of the second layer 620 and formed of a material same as the first layer 610.

According to an embodiment, the bank portion 600 may be formed with a predetermined (e.g., specified) height H (see FIG. 7) so that the plurality of cells are selectively filled (or disposed) with a first color conversion layer 330, a second color conversion layer 430, and a transparent layer 530.

According to an embodiment, in the plurality of cells provided on the substrate 221 by the bank portion 600, the sub-pixels 300, 400, and 500 are disposed one by one, and first and second substrate electrode pads 225 and 226 may be disposed.

According to an embodiment, the first and second substrate electrode pads 225 and 226 may be electrically connected to first and second electrodes 351 and 352 of corresponding light emitting element, respectively.

In the disclosure, by way of non-limiting illustrative example, it will be described with the example in which the one pixel P disposed in the one pixel area 215 (see FIG. 4) includes the first to third sub-pixels 300, 400, and 500.

According to an embodiment, the first sub-pixel 300 may include a first light emitting element 310 and the first color conversion layer 330. The first light emitting element 310 may be, for example, and without limitation, a micro light emitting diode (LED) that emits light in a blue wavelength band with an intensity of approximately 50 μm or less.

According to an embodiment, the first color conversion layer 330 may be disposed to cover at least a light emitting surface of the first light emitting element 310. The bank portion 600 may be spaced apart from the first light emitting element 310 by a predetermined (e.g., specified) distance L (see FIG. 7), and accordingly, the first color conversion layer 330 may be disposed to cover all of the light emitting surface 314 and side surfaces 317 of the first light emitting element 310. In this case, a gap provided between a bottom surface 312 of the first light emitting element 310 and an upper surface 223 of the substrate 221 may be filled depending on a viscosity of a color conversion material forming the first color conversion layer 330.

According to an embodiment, the first color conversion layer 330 may include a red phosphor capable of emitting light in a red wavelength band by excitation by light emitted from the first light emitting element 310.

According to an embodiment, the second sub-pixel 400 may include a second light emitting element 410 and the second color conversion layer 430. For the second light emitting element 410, for example, the same micro LED as the first light emitting element 310 may be applied. The second color conversion layer 430 may be disposed to cover all of a light emitting surface and side surfaces of the second light emitting element 410 or may be disposed to cover at least the light emitting surface of the second light emitting element 410. The second color conversion layer 430 may include a green phosphor capable of emitting light in a green wavelength band by excitation by light emitted from the second light emitting element 410.

According to an embodiment, the third sub-pixel 500 may include a third light emitting element 510 and the transparent layer 530. For the third light emitting element 510, the same micro LED as the first light emitting element 310 may be applied. The transparent layer 530 may be disposed to cover all of a light emitting surface and side surfaces of the third light emitting element 510 or may be disposed to cover at least the light emitting surface of the third light emitting element 510. The transparent layer 530 may be formed of a transparent material capable of not affecting or minimizing or reducing the effect on a transmittance, a reflectivity, and a reflectance of light emitted from the third light emitting element 510. For the transparent layer 530, a material such as an optical film material capable of minimizing and/or reducing light waste and enhancing luminance by causing a light emitting direction of the light to face a front surface of the display panel 210 through refraction and reflection may be used.

In the disclosure, it is described that the first to third light emitting elements 310, 410, and 510 are all blue micro LEDs which emit light in the blue wavelength band, but there is no limitation thereto.

For example, for the second light emitting element 410, a green micro LED which emits light in a green wavelength band may be applied, and a transparent layer may be disposed instead of the second color conversion layer on a side of the light emitting surface of the second light emitting element 410.

According to an embodiment, for all of the first to third light emitting elements 310, 410, and 510, a UV micro LED which emits light in an ultraviolet wavelength band may be applied. In this case, the first sub-pixel 300 may include the first light emitting element 310 and a first color conversion layer including a red phosphor which emits light in a red wavelength band using light of the first light emitting element 310 as excitation light. The second sub-pixel 400 may include the second light emitting element 410 and a second color conversion layer including a green phosphor which emits light in a green wavelength band using light of the second light emitting element 410 as excitation light. The third sub-pixel 500 may include the third light emitting element 510 and a third color conversion layer including a blue phosphor which emits light in a blue wavelength band using light of the third light emitting element 510 as excitation light. As described above, in a case of the display panel 210 in which the UV micro LED is applied for the first to third light emitting elements 310, 410, and 510, a UV cut filter (not illustrated) for cutting ultraviolet light from the light emitted from the first to third color conversion layers may be further provided.

According to an embodiment, for all of the first to third light emitting elements 310, 410, and 510, a micro LED which emits white light may be applied. In this case, the first sub-pixel 300 may include the first light emitting element and a first color conversion layer including a red phosphor which emits light in a red wavelength band using light of the first light emitting element as excitation light. The second sub-pixel 400 may include the second light emitting element and a second color conversion layer including a green phosphor which emits light in a green wavelength band using light of the second light emitting element as excitation light. The third sub-pixel 500 may include the third light emitting element and a third color conversion layer including a blue phosphor which emits light in a blue wavelength band using light of the third light emitting element as excitation light.

According to an embodiment, after each cell provided on the substrate 221 by the bank portion 600 is filled with the color conversion material for forming the first color conversion layer 330 and the second color conversion layer 430 and the transparent material for forming the transparent layer 530, an encapsulation layer 700 may be formed on an upper portion of the bank portion 600.

According to an embodiment, the encapsulation layer 700 may be formed in a multilayered structure of one or more inorganic layers and organic layers. The encapsulation layer 700 may be formed of a transparent material with a strength capable of protecting the sub-pixels 300, 400, and 500 and the bank portion 600 from an external impact. In addition, a material forming the encapsulation layer 700 may be a material capable of not affecting or minimizing and/or reducing the effect on a transmittance, a reflectivity, and a reflectance of light. The display panel 210 according to an embodiment of the disclosure may enhance durability by providing the encapsulation layer 700.

Hereinafter, referring to FIG. 7, the structure of the first light emitting element 310 and the structure of the bank portion 600 will be described. The structure of the second and third light emitting elements 410 and 510 is the same as the structure of the first light emitting element 310, and therefore the description thereof will be not repeated.

Referring to FIG. 7, the light emitting element 310 may include a first semiconductor layer 311, a second semiconductor layer 313, an active layer 315 formed between the first semiconductor layer 311 and the second semiconductor layer 313, and the first electrode 351 and the second electrode 352.

According to an embodiment, the first semiconductor layer 311, the active layer 315, and the second semiconductor layer 313 may be formed using a method such as, for example, and without limitation, metal organic chemical vapor deposition (MOCVD), chemical vapor deposition (CVD), plasma-enhanced chemical vapor deposition, or the like.

According to an embodiment, the first semiconductor layer 311 may include, for example, and without limitation, a p-type semiconductor layer (anode). The p-type semiconductor layer may be selected from, for example, and without limitation, GaN, AlN, AlGaN, InGaN, InN, InAlGaN, AlInN, and the like, and may be doped with a p-type dopant such as, for example, and without limitation, Mg, Zn, Ca, Sr, Ba, and the like.

According to an embodiment, the second semiconductor layer 313 may include, for example, and without limitation, an n-type semiconductor (cathode). The n-type semiconductor layer may be selected from, for example, and without limitation, GaN, AlN, AlGaN, InGaN, InN, InAlGaN, AlInN, and the like and may be doped with an n-type dopant such as, for example, and without limitation, Si, Ge, Sn, and the like.

Meanwhile, the light emitting element is not limited to the above configuration, and the first semiconductor layer 311 may include an n-type semiconductor layer and the second semiconductor layer 313 may include a p-type semiconductor layer.

According to an embodiment, the active layer 315 may be a region where electrons and positive holes are recombined, the energy transitions to a low energy level according to the recombination of the electrons and positive holes, and light having a wavelength corresponding thereto may be generated. The active layer 315 may include a semiconductor material, for example, amorphous silicon or polycrystalline silicon. However, the embodiment is not limited thereto, and the active layer may contain, for example, and without limitation, an organic semiconductor material, and may be formed, for example, and without limitation, in a single quantum well (SQW) structure or a multi quantum well (MQW) structure, or the like.

According to an embodiment, the first electrode 351 is for electrical connection between the first semiconductor layer 311 and the first substrate electrode pad 225 and may be disposed on the first semiconductor layer 311. The second electrode 352 is for electrical connection between the second semiconductor layer 313 and the second substrate electrode pad 226 and may be disposed on the second semiconductor layer 313. The first and second electrodes 351 and 352 may, for example, be formed of Au or an alloy containing Au but is not limited thereto.

In the disclosure, the bank portion 600 may be formed with multiple layers. For example, the bank portion 600 may include the first layer 610 disposed on the upper surface 223 of the substrate 221, the second layer 620 that is formed on the upper portion of the first layer 610 and formed of a material different from the first layer 610, and the third layer 630 that is formed on the upper portion of the second layer 620 and formed of a material same as the first layer 610. According to an embodiment, the bank portion 600 may, for example, include an organic material such as, for example, and without limitation, a polyacrylates resin or a polyimides resin or silica-based inorganic material. According to an embodiment, the first layer 610 may, for example, be formed of a material having a blackish color with a high optical density and low reflectivity, in order to enhance a contrast ratio and ensure visibility of black color by reducing interference between adjacent light emitting elements. The material forming the first layer 610 may have reflectivity of approximately 9% or less in the entire wavelength region of visible light (e.g., 390 nm to 700 nm).

According to an embodiment, the first layer 610 may be printed in a lattice pattern on the upper surface 223 of the substrate. A height H1 of the first layer 610 may be lower than a height H4 of the active layer 315 of the first light emitting element 310. Herein, the height H1 of the first layer may be a length from the upper surface 223 of the substrate to an upper end of the first layer 610, and the height H4 of the active layer 315 may be a length from the upper surface 223 of the substrate to a lower end of the active layer 315. As described above, by setting the height H1 of the first layer to be lower than the height H4 of the active layer 315, the amount of light absorbed by the first layer 610 may be minimized and/or reduced from the entire amount of light of side light emitted from the side surface of the first light emitting element 310. Accordingly, by causing the most of the entire amount of light of the side light emitted from the side surface of the first light emitting element 310 to be reflected by the second layer 620 to be incident to the first color conversion 300, light efficiency of the first sub-pixel 300 may be maximized and/or improved.

According to an embodiment, the second layer 620 may be formed of a material having a high reflectivity capable of reflecting the side light of the first light emitting element 310. For example, the material forming the second layer 620 may have an optical density of approximately 1.5 or more and a reflectivity of approximately 20% based on the blue light.

According to an embodiment, the second layer 620 may be formed on the first layer 610 through, for example, an ink jet method for discharging the material at regular width. The second layer 620 may have a height H2 capable of realizing a high aspect ratio, in order to sufficiently fill the pixel area (or cell formed by the bank portion) with the color conversion material forming the first color conversion layer 330 or the second color conversion layer 430. For example, the second layer 620 may be implemented with a width W of approximately 20 μm or less and an aspect ratio (H2:W) of 1.0 or more. If the second layer 620 is formed with a longitudinal cross section substantially in a trapezoidal shape, as illustrated in FIG. 7, the W representing the width of the second layer 620 may refer to an average value of the width of the second layer 620, and if the longitudinal cross section of the second layer 620 has substantially a rectangular shape, the W may refer to a value corresponding to a short side of the rectangle. Here, the height H2 of the second layer 620 may have a length from the upper end of the first layer 610 and an upper end of the second layer 620.

According to an embodiment, the third layer 630 may be formed of a material same as the first layer 610 and may play a role of black matrix. For example, the third layer 630 may enhance outdoor visibility by enhancing the contrast ratio and visibility of black color of the display by addressing a problem due to reflection of external light. According to an embodiment, the third layer 630 may enhance color reproducibility of the display by preventing and/or reducing the mixing of light rays having different colors emitted from the adjacent light emitting elements. For example, the third layer 630 may include a light shielding material and shield the light. For example, if the third layer 630 includes the light shielding material, the mixing of colors of light generated from the active layer 315 of the first sub-pixel 300 and light generated from the active layer of the adjacent pixel (e.g., second sub-pixel 400, third sub-pixel 500).

According to an embodiment, a height H3 of the third layer 630 may be enough as long as the third layer 630 has a minimum height capable of performing the role of the black matrix. For example, the height H3 of the third layer 630 may be similar to the height H1 of the first layer 610 or less than the height H2 of the second layer 620.

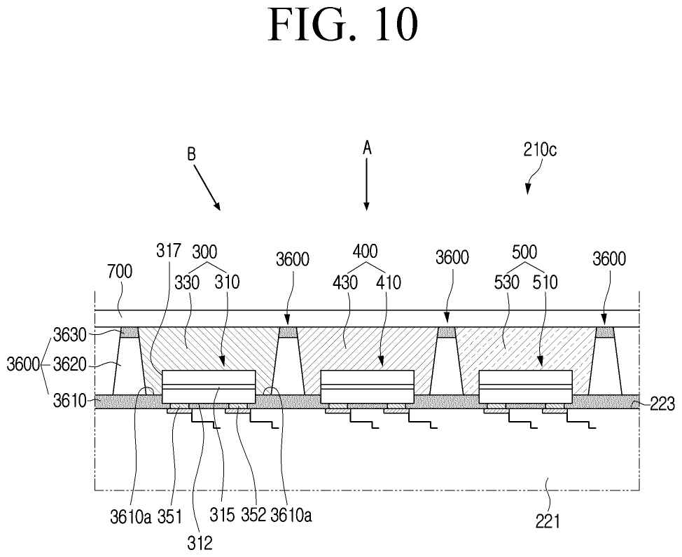

According to an embodiment, the bank portion 600 may have the longitudinal cross section formed substantially in a trapezoidal shape, as illustrated in FIG. 7. If the longitudinal cross section of the bank portion 600 is formed in a trapezoidal shape, at least a part of the second layer 620 corresponding to a reflection section of the bank portion 600 may be visible when the display panel 120 is seen from the front surface (see direction A of FIG. 10), the width of the third layer 630 corresponding to the reflectivity reduction section may be further enlarged to enhance the visibility of black color. For this, for example, the longitudinal cross section of the bank portion 600 may be formed in a reversed trapezoidal shape. The longitudinal cross section of the bank portion 600 may be formed in various shapes such as a rectangle, square, and the like, in addition to the trapezoid or reversed trapezoid described above.

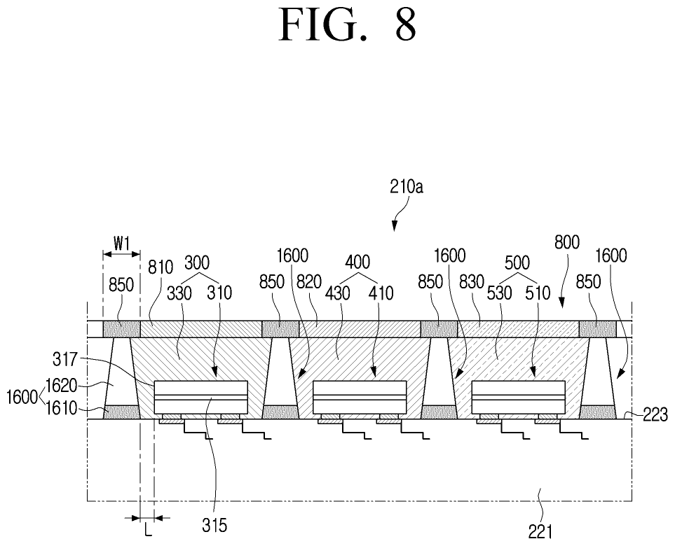

Hereinafter, display panels 210a, 210b, 210c, 210d, 210e, and 210f corresponding to various embodiments according to the disclosure will be described with reference to FIGS. 8, 9, 10, 11, 12, 13, 14 and 15, but the same reference numerals are applied to the same configurations as the configurations of the display panel 210 (see FIG. 6), and the configuration different from the display panel 210 will be mainly described. In the disclosure, the expression “same” may not only include complete coincident, but also include differences by allowing manufacturing error ranges or the term “similar”.

FIG. 8 is a cross-sectional view illustrating an example pixel structure of a display panel 210a according to various embodiments.

Referring to FIG. 8, the display panel 210a may include a bank portion 1600 laminated (or disposed) as two layers on the substrate 221. For example, the bank portion 1600 may include a first layer 1610 disposed on the upper surface 223 of the substrate 221 and a second layer 1620 formed on the upper portion of the first layer 1610.

According to an embodiment, the first layer 1610 may be formed of a material having blackish color that is the same or similar to the first layer 610 of the bank portion 600 described above (see FIG. 7). For example, the material forming the first layer 1610 may have a high optical density and a reflectivity of approximately 9% or less in the entire wavelength region of the visible light, in order to enhance the contrast ratio and ensure the visibility of black colors by reducing the interference between adjacent light emitting elements.

According to an embodiment, the first layer 1610 may be printed on the upper surface 223 of the substrate in a lattice pattern. Since the height of the first layer 1610 is formed to be lower than the height of the active layer 315 of the first light emitting element 310, the amount of light absorbed by the first layer 1610 may be minimized and/or reduced from the entire amount of light of the side light emitted from the side surfaces of the first to third light emitting elements 310, 410, and 510.

According to an embodiment, the second layer 1620 may be formed of a material same or similar to the second layer 620 of the bank portion 600 (see FIG. 7). For example, the second layer 1620 may have an optical density of approximately 1.5 or more and a reflectivity of approximately 20% or more based on the blue light. The second layer 1620 may reflect the side light of the first and second light emitting elements 310 and 410 so that the light is incident to the first and second color conversion layers 330 and 430. Accordingly, the light efficiency of the first and second sub-pixels 300 and 400 may be maximized and/or improved using the light emitted from the light emitting surface and side surface of each light emitting elements 310 and 410.

In addition, the second layer 1620 may reflect the side light of the third light emitting element 510 so that this light is emitted to the front of the display panel 210a along with the light emitted from the light emitting surface of the third light emitting element 510 through the transparent layer 530. Accordingly, the light efficiency of the third sub-pixel 500 may be maximized and/or improved.

According to an embodiment, the second layer 1620 may be formed on the upper portion of the first layer 1610 through, for example, the ink jet method for discharging the material at regular width. The height of the second layer 1620 may have, for example, a length obtained by adding the height H2 of the second layer 620 and the height H3 of the third layer 630 of the bank portion 600 (see FIG. 7) together. However, the height of the second layer 1620 is not limited thereto, and the height thereof is enough as long as it has a high aspect ratio to sufficiently fill the pixel area (or cell formed by the bank portion) with the color conversion material forming the first color conversion layer 330 or the second color conversion layer 430.

According to an embodiment, the display panel 210a may include a color filter layer 800 to enhance the color reproducibility. The color filter layer 800 may be disposed at a location covering the first to third sub-pixels 300, 400, and 500 and the bank portion 1600 together.

Although not illustrated in the drawing, before disposing the color filter layer 800, a flattening layer may be formed on the first to third sub-pixels 300, 400, and 500 and the bank portion 1600. In this case, the color filter layer 800 may be disposed on the flattening layer. According to an embodiment, the encapsulation layer may be formed on the flattening layer and the color filter layer 800 may be disposed on an upper portion of the encapsulation layer.

According to an embodiment, the color filter layer 800 may include an organic material pattern containing a dye or a pigment. The color filter layer 800 may include a first color filter 810, a second color filter 820, and a transmission layer 830 corresponding to the first color conversion layer 330, the second color conversion layer 430, and the transparent layer 530, respectively.

According to an embodiment, the first color filter 810 selectively transmits only light emitted from the first light conversion layer 330 and the second color filter 820 selectively transmits only light emitted from the second color conversion layer 430.

According to an embodiment, the transmission layer 830 may emit light substantially the same as the incident light, without converting the light transmitted through the transparent layer 530. For example, the blue light incident to the transmission layer 830 may be emitted as it is. The transmission layer 830 may include a scattering material for scattering the incident light. For example, the transmission layer 830 may include, for example, and without limitation, any one of ZrO₂, Al₂O₃, In₂O₃, ZnO, SnO₂, Sb₂O₃, and ITO. However, the material of the transmission layer 830 is not limited thereto and may be variously changed, as long as it is a material scattering the blue light rather than converting the light.

According to an embodiment, the color filter layer 800 may include a black matrix 850 for dividing the first color filter 810, the second color filter 820, and the transmission layer 830.

According to an embodiment, the black matrix 850 may be formed in a lattice shape corresponding to the bank portion 1600. The black matrix 850 may be disposed to correspond on the upper end of the bank portion 1600, for example, the upper portion of the second layer 1620. A width W1 of the black matrix 850 may be larger than or the same as an average width of the second layer 1620.

According to an embodiment, lights with different colors that are emitted by being transmitted through the first color filter 810, the second color filter 820, and the transmission layer 830 of the color filter layer 800 may be prevented or reduced from being mixed by the black matrix 850 and color purity is enhanced according to the transmission through the first and second color filters 810 and 820, thereby enhancing the color reproducibility and the contrast ratio of the display panel 210a. For example, in the display panel 210a, a polarization layer (or circular polarization layer) may be omitted, and in this case, the black matrix 850 may play a role of shielding the reflection of external light instead of the polarization layer.

Although not illustrated, the display panel 210a may include a protection layer for covering the color filter layer 800 to protect the color filter layer 800 from the external impact. In this case, the material of the protection layer may be a transparent material formed of a material that has a predetermined strength and does not disturb light projection.

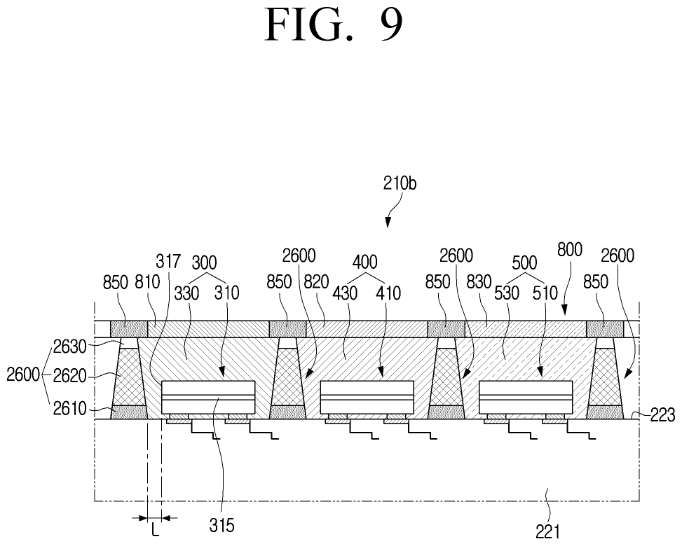

FIG. 9 is a cross-sectional view illustrating an example pixel structure of the display panel 210b according to various embodiments.

Referring to FIG. 9, the display panel 210b may include a bank portion 2600 laminated as three layers on the substrate 221 and the color filter layer 800 (see FIG. 8) may be disposed on an uppermost portion.

According to an embodiment, the bank portion 2600 may include a first layer 2610 disposed on the upper surface 223 of the substrate 221, a second layer 2620 formed on an upper portion of the first layer 2610, and a third layer 2630 formed on an upper portion of the second layer 2620.

According to an embodiment, the first to third layers 2610, 2620, and 2630 may be formed of materials different from each other. For example, the first layer to third layer 2610, 2620, and 2630 may be formed of materials with higher light reflectivity gradually from the first layer towards the third layer (light reflectivity of the first layer 2610<light reflectivity of the second layer 2620<light reflectivity of the third layer 2630).

The first layer 2610 may be formed of a material having blackish color that is the same or similar to the first layer 610 of the bank portion 600 described above (see FIG. 7). For example, the material forming the first layer 2610 may have a high optical density and a reflectivity of approximately 9% or less in the entire wavelength region of the visible light, in order to enhance the contrast ratio and ensure the visibility of black colors by reducing the interference between adjacent light emitting elements.

According to an embodiment, the first layer 2610 may be printed on the upper surface 223 of the substrate in a lattice pattern. Since the height of the first layer 2610 is formed to be lower than the height of the active layer 315 of the first light emitting element 310, the amount of light absorbed by the first layer 2610 may be minimized and/or reduced from the entire amount of light of the side light emitted from the side surfaces of the first to third light emitting elements 310, 410, and 510.

According to an embodiment, the second layer 2620 may be formed of a material same or similar to the second layer 620 of the bank portion 600 (see FIG. 7). For example, the second layer 2620 may have an optical density of approximately 1.5 or more and a reflectivity of approximately 20% or more based on the blue light. The second layer 2620 may reflect the side light of the first and second light emitting elements 310 and 410 so that the light is incident to the first and second color conversion layers 330 and 430. Accordingly, the light efficiency of the first and second sub-pixels 300 and 400 may be maximized and/or improved using the light emitted from the light emitting surface and side surface of each light emitting elements 310 and 410.

In addition, the second layer 2620 may reflect the side light of the third light emitting element 510 so that this light is emitted to the front of the display panel 210b along with the light emitted from the light emitting surface of the third light emitting element 510 through the transparent layer 530. Accordingly, the light efficiency of the third sub-pixel 500 may be maximized and/or improved.

According to an embodiment, the second layer 2620 may be formed on the upper portion of the first layer 2610 through, for example, the ink jet method for discharging the material at regular width. The height of the second layer 2620 may have, for example, an approximately similar height as the height H2 of the second layer 620 of the bank portion 600 (see FIG. 7). However, the height of the second layer 2620 is not limited thereto, and the height thereof is enough as long as it has a high aspect ratio to sufficiently fill the pixel area (or cell formed by the bank portion) with the color conversion material forming the first color conversion layer 330 or the second color conversion layer 430.

According to an embodiment, the third layer 2630 may be formed on an upper portion of the second layer 2620 and may be formed with a width smaller than or same as the width of the second layer 2620. The third layer 2630 may be formed of a material having a reflectivity higher than the reflectivity of the second layer 2620.

Accordingly, the bank portion 2600 of the display panel 210b may reflect the side light of each light emitting elements 300, 400, and 500 through the third layer 2630 in addition to the second layer 2620, which maximizes and/or improves the amount of light emitted from the first and second color conversion layers 330 and 430 and the transparent layer 530, thereby maximizing and/or improving the light efficiency of the display panel 210b.

Referring to FIG. 9, it is illustrated that the height of the third layer 2630 is formed to be lower than the height of the second layer 2620, but is not limited thereto. For example, the height of the third layer 2630 may be the same as the height of the second layer 2620 and may also be formed to be higher than the height of the second layer 2620. In this case, the sum of the height of the second layer 2620 and the height of the third layer 2630 may be formed to satisfy a high aspect ratio (e.g., aspect ratio of 1.0 or more).

According to an embodiment, the black matrix 850 of the color filter layer 800 may be disposed at the location corresponding to the third layer 2630. Accordingly, although the third layer 2630 is formed of the material having the reflectivity higher than the reflectivity of the second layer 2620, the lights of different colors emitted from the adjacent sub-pixels may be separated through the black matrix 850 disposed on the upper portion of the third layer 2630, thereby enhancing the contrast ratio.

FIG. 10 is a cross-sectional view illustrating an example pixel structure of the display panel 210c according to various embodiments.

Referring to FIG. 10, the display panel 210c may include a bank portion 3600 laminated as three layers on the substrate 221 and the encapsulation layer 700 (see FIG. 6) may be disposed on an uppermost portion.

According to an embodiment, the bank portion 3600 may include a first layer 3610 disposed on the upper surface 223 of the substrate 221, a second layer 3620 formed on an upper portion of the first layer 3610, and a third layer 3630 formed on an upper portion of the second layer 3620.

According to an embodiment, the first layer 3610 may be formed of a material having blackish color that is the same or similar to the first layer 610 of the bank portion 600 described above (see FIG. 7). For example, the material forming the first layer 3610 may have a high optical density and a reflectivity of approximately 9% or less in the entire wavelength region of the visible light, in order to enhance the contrast ratio and ensure the visibility of black colors by reducing the interference between adjacent light emitting elements.

According to an embodiment, the first layer 3610 may be printed on the upper surface 223 of the substrate in a lattice pattern. Since the height of the first layer 3610 is formed to be lower than the height of the active layer 315 of the first light emitting element 310, the amount of light absorbed by the first layer 3610 may be minimized and/or reduced from the entire amount of light of the side light emitted from the side surfaces of the first to third light emitting elements 310, 410, and 510.

According to an embodiment, the first layer 3610 may be formed to the location coming into contact with the side surface 317 of the first light emitting element 310. In this case, a gap provided between the bottom surface 312 of the first light emitting element 310 and the upper surface 223 of the substrate 221 may be filled depending on a viscosity of the material forming the first layer 3610.

According to an embodiment, the side surface of the first light emitting element 310 may be fixed by the first layer 3610 and solidly attached to the substrate 221, thereby enhancing durability. The side surfaces of the second and third light emitting elements 410 and 510 may also be fixed to the first layer 3610, and accordingly may be solidly attached to the substrate 221.

According to an embodiment, the second layer 3620 may be disposed on the upper portion of the first layer 3610. A width of the first layer 3610 may be formed to be larger than a width of the second layer 3620, and accordingly, a region 3610a of the first layer 3610 may not be covered by the second layer 3620. The uncovered region 3610a of the first layer 3610 may contribute to enhancement of the contrast ratio of the display panel 210c. For example, in addition to when the user sees the display panel 210c from the front (see direction A illustrated in FIG. 10), when the user sees the display panel 210c in an oblique direction (see direction B illustrated in FIG. 10), the region 3610a of the first layer 3610 may be visually recognized thereby enhancing the visibility of black colors.

According to an embodiment, the second layer 3620 may be formed of a material same or similar to the second layer 620 of the bank portion 600 (see FIG. 7). For example, the second layer 3620 may have an optical density of approximately 1.5 or more and a reflectivity of approximately 20% or more based on the blue light. The second layer 3620 may reflect the side light of the first and second light emitting elements 310 and 410 so that the light is incident to the first and second color conversion layers 330 and 430. Accordingly, the light efficiency of the first and second sub-pixels 300 and 400 may be maximized and/or improved using the light emitted from the light emitting surface and side surface of each light emitting elements 310 and 410.

In addition, the second layer 3620 may reflect the side light of the third light emitting element 510 so that this light is emitted to the front of the display panel 210c along with the light emitted from the light emitting surface of the third light emitting element 510 through the transparent layer 530. Accordingly, the light efficiency of the third sub-pixel 500 may be maximized and/or improved.

According to an embodiment, the second layer 3620 may be formed on the upper portion of the first layer 3610 through the ink jet method for discharging the material at regular width. The height of the second layer 3620 may have, for example, an approximately similar height as the height H2 of the second layer 620 of the bank portion 600 (see FIG. 7). However, the height of the second layer 3620 is not limited thereto, and the height thereof is enough as long as it has a high aspect ratio to sufficiently fill the pixel area (or cell formed by the bank portion) with the color conversion material forming the first and second color conversion layers 330 and 430 and the material forming the transparent layer 530.

According to an embodiment, the third layer 3630 may be formed of a material same as the first layer 3610 and may play a role of black matrix. For example, the third layer 3630 may enhance outdoor visibility by enhancing the contrast ratio and visibility of black color of the display by resolving a problem due to reflection of external light. In addition, the third layer 3630 may enhance color reproducibility of the display by preventing and/or reducing the mixing of light rays having different colors emitted from the adjacent light emitting elements. The height of the third layer 3630 may be enough with a minimum height so that the third layer 360 may play the role of the black matrix.

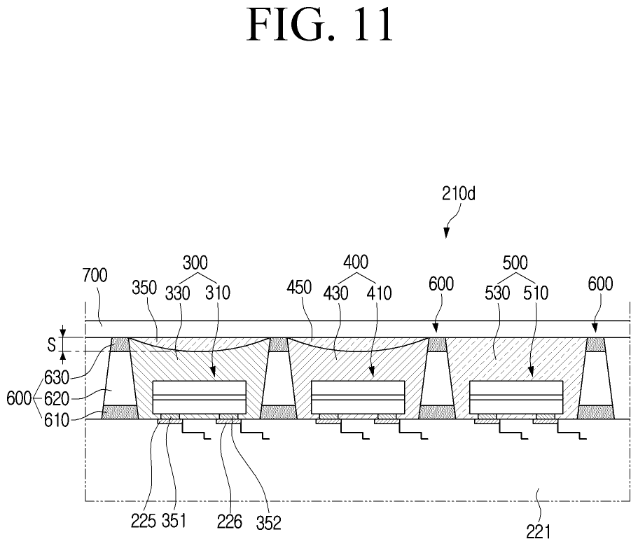

FIG. 11 is a cross-sectional view illustrating a pixel structure of the display panel 210d according to various embodiments.

Referring to FIG. 11, the most configuration of the display panel 210d may be formed to be the same or similar to the configuration of the display panel 210 (see FIG. 6), and therefore in describing the display panel 210d, the configuration different from the display panel 210 described above will be described.

According to an embodiment, the material forming the first and second color conversion layers 330 and 430 may be formed of a liquid having a viscosity and may be discharged from a nozzle (not illustrated) by an ink jet method to be filled in the cell provided by the bank portion 600.

According to an embodiment, during a step of filling the liquid-phase material forming the first and second color conversion layers 330 and 430, the material may be dried thereby reducing thicknesses of the first and second color conversion layers 330 and 430. For example, referring to FIG. 11, as the first and second color conversion layers 330 and 430 contract, recessed grooves may be formed on the upper surfaces of the first and second color conversion layers 330 and 430.

In this case, a step S may be generated between the upper end of the bank portion 600 and the upper surfaces of the first and second color conversion layers 330 and 430. In order to compensate the step S, first and second flattening layers 350 and 450 may be formed respectively on the recessed grooves of the upper surfaces of the first and second color conversion layers 330 and 430.

According to an embodiment, the first and second flattening layers 350 and 450 may include a scattering material which scatters the incident light that is emitted from the first and second color conversion layers 330 and 430. For example, the first and second flattening layers 350 and 450 may include, for example, and without limitation, any one of TiO₂, ZrO₂, Al₂O₃, In₂O₃, ZnO, SnO₂, Sb₂O₃, ITO, or the like. However, the first and second flattening layers 350 and 450 are not limited thereto and may be variously changed, as long as it is a material scattering the blue light rather than converting the light.

As described above, by forming the first and second flattening layers 350 and 450 on the upper recessed surfaces of the first and second color conversion layers 330 and 430 to match to the height of the upper end of the bank portion 600, a deterioration in visibility due to the step S may be enhanced.

According to an embodiment, the transparent layer 530 forming the third sub-pixel 500 may include a light scattering material, in the same manner as the first and second flattening layers 350 and 450. In this case, the transparent layer 530 may scatter the incident light that is emitted from the third light emitting element 510 to enhance the light efficiency.

As described above, the first and second flattening layers 350 and 450 may be formed respectively on the recessed grooves formed on the upper surfaces of the first and second color conversion layers 330 and 430 due to the contraction of the first and second color conversion layers 330 and 430, but there is no limitation thereto.

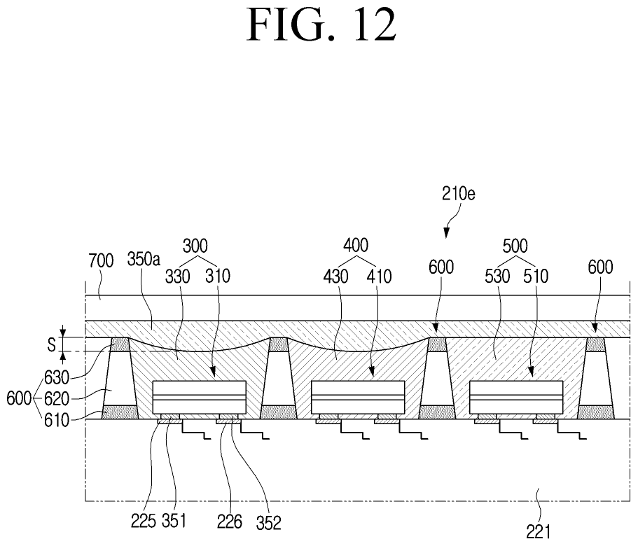

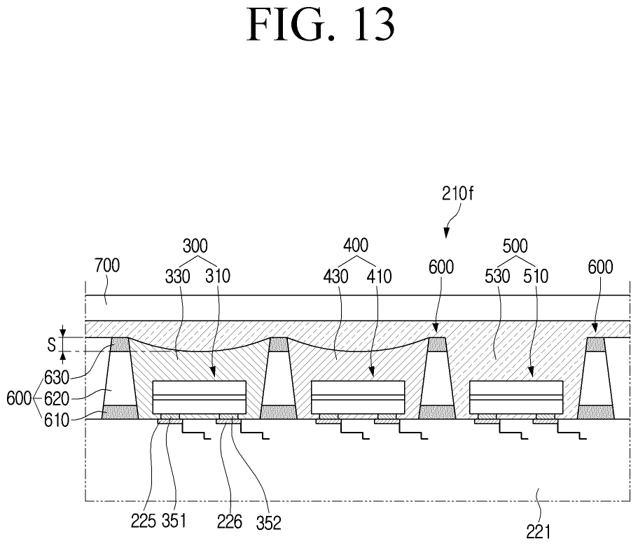

Referring to FIGS. 12 and 13, the most configuration of the display panels 210e and 210f may be formed to be the same or similar to the configuration of the display panel 210 (see FIG. 6), and therefore in describing the display panels 210e and 210f, the configuration different from the display panel 210 described above will be described.

According to an embodiment, referring to FIG. 12, in the display panel 210e, a flattening layer 350a may be formed on the recessed grooves of the upper surfaces of the first and second color conversion layers 330 and 430, and the flattening layer 350a may be formed to cover even the transparent layer 530 and the bank portion 600. In this case, the encapsulation layer 700 may be disposed on the upper surface of the flattening layer 350a. According to an embodiment, referring to FIG. 13, in the display panel 210f, when filling the cell where the third light emitting element 510 with the transparent layer 530, the recessed grooves of the upper surfaces of the first and second color conversion layers 330 and 430 may be filled with the transparent layer 530. In this case, the transparent layer 530 may cover the upper portion of the bank portion 600. As described above, the transparent layer 530 may play the role of the flattening layer since it may cover also the first and second color conversion layers 330 and 430, the third light emitting element 510, and the bank portion 600. In this case, the encapsulation layer 700 may be disposed on the upper surface of the transparent layer 530.

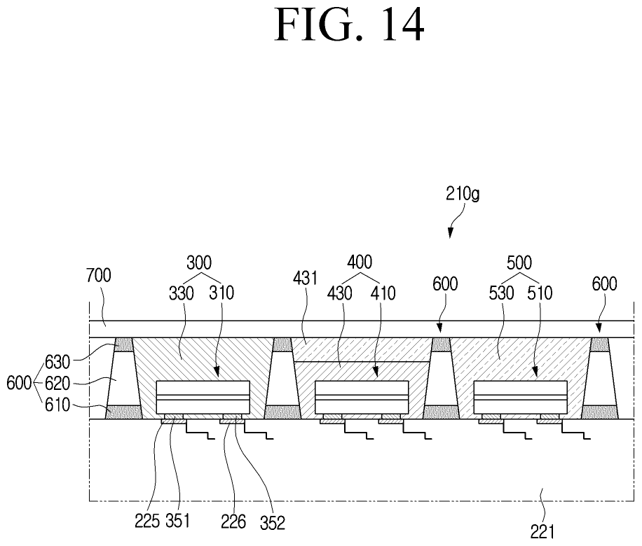

According to an embodiment, referring to FIG. 14, in a display panel 210g, if the first and second color conversion layers 330 and 430 are color conversion layers which convert light into light with different colors, there may be a difference in light conversion rate for each color. In this case, the difference in light conversion rate may be maintained in the same or similar manner, by differently setting the color conversion materials filled between the bank portion 600. For example, if the first color conversion layer 330 converts the light incident from the light emitting element 310 into red light and the second color conversion layer 430 converts the light incident from the light emitting element 410 into green light, the light conversion rate of the second color conversion layer 430 may be higher than the light conversion rate of the first color conversion layer 330. In this case, the height (or thickness) of the second color conversion layer 430 may be formed to be less than the height (or thickness) of the first color conversion layer 330.

For example, if the height (or thickness) of the second color conversion layer 430 is formed to be small, a step may be provided between the upper surface of the second color conversion layer 430 and the upper end of the bank portion 600. In order to compensate for the step, a transparent material may be filled on the second color conversion layer 430 to form a transparent layer 431. For example, the transparent layer 431 may be formed of a material substantially the same as the transparent layer 530 of the third sub-pixel 500.

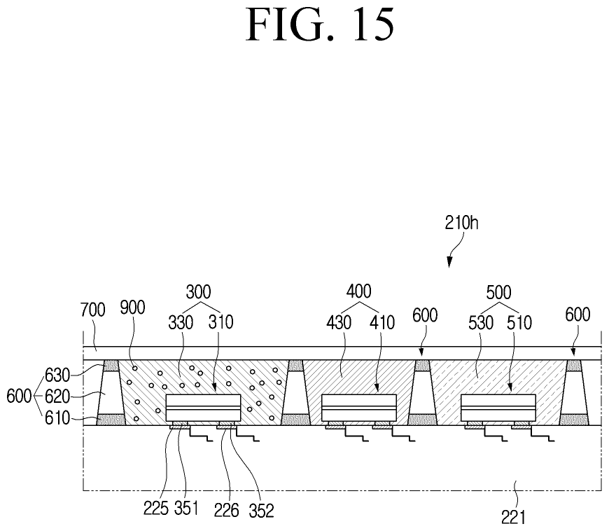

According to an embodiment, referring to FIG. 15, in a display panel 210h, the heights (or thicknesses) of the first and second color conversion layers 330 and 430 may be set to be the same, but the amounts of the first and second color conversion layers 330 and 430 may be set to be different in consideration of the light conversion rate. In this case, as the size (or area) of the first color conversion layer 330 increases, the size (or area) of the light emitting element 310 may be relatively smaller. Accordingly, in the entire area of the first color conversion layer 330, the amount of light incident from the light emitting element 310 may be gradually reduced as it goes to a peripheral portion from the center where the light emitting element 310 is located. In this case, a light scattering agent 900 may be evenly distributed in the first color conversion layer 330 to enhance the light efficiency of the converted light (e.g., red light) emitted from the entire area of the first color conversion layer 330.

The display module 160 according to various example embodiments of the disclosure may include the display panel 210 and the driving circuit 230 configured to generate a driving signal of the plurality of light emitting elements provided in the display panel. The display panel 160 may include the substrate 221, the plurality of light emitting elements 310, 410, and 510 mounted on the substrate, the bank portion 600 disposed on the substrate to space the plurality of light emitting elements apart from each other, the color conversion layers 330 and 430 filled in the cells partitioned by the bank portion to cover the light emitting elements, and the encapsulation layer 700 covering the bank portion and the color conversion layers. The bank portion 600 includes the first layer 610 having a thickness less than the active layer of the light emitting element, and the second layer 620 laminated on the first layer and spaced apart from the side surface of the light emitting element and configured to reflect the light emitted from the side surface of the light emitting element. Accordingly, the amount of light emitted from the light emitting element may be maximized and/or improved using the side light of the light emitting element to enhance the light efficiency, and the optical interference between adjacent pixels may be minimized and/or reduced in the high-definition mobile device to enhance image quality.

According to various example embodiments, the first layer 610 may have a blackish color.

According to various example embodiments, the first layer 610 may have a reflectivity less than the reflectivity of the second layer 620.

According to various example embodiments, the first layer 610 may have light reflectivity of approximately 9% or less.

According to various example embodiments, the first layer may come into close contact with the side surface of the light emitting element.

According to various example embodiments, the width of the first layer 610 may be greater than the width of the second layer.

According to various example embodiments, the region 3610a of the upper surface of the first layer 3610 may not be covered by the second layer 3620.

According to various example embodiments, the upper end of the second layer 620 may be at a location higher than the light emitting surface of the light emitting element.

According to various example embodiments, the second layer 620 may have the light reflectivity of approximately 20% or more and the optical density of approximately 1.5 or more.

According to various example embodiments, the bank portion 600 may further include the third layer 630 laminated (or disposed) on the second layer.

According to various example embodiments, the third layer 630 may have a blackish color.

According to various example embodiments, the third layer 630 may have the light reflectivity of approximately 9% or less.

According to various example embodiments, the width of the third layer 630 may be less than the width of the second layer.

According to various example embodiments, the space between the upper surface of the substrate and the bottom surface of the light emitting element may be filled with the first layer 3610.

According to various example embodiments, the space between the bank portion and the side surface of the light emitting element may be filled with the color conversion layers 330 and 430.

According to various example embodiments, the space between the upper surface of the substrate and the bottom surface of the light emitting element may be filled with the color conversion layers 330 and 430.

According to various example embodiments, the display module 160 may further include the flattening layers 350, 450, and 350a laminated on the color conversion layers, and the upper surface of the flattening layer may coincide with the upper end of the bank portion.

According to various example embodiments, the flattening layers 350, 450, and 350a may contain the light scattering material.

According to various example embodiments, the display module 160 may further include the color filter layer 800 disposed on the upper side of the encapsulation layer, and the color filter layer may include the color filters 810 and 820 for different colors, the transmission layer 830, and the black matrix 850 corresponding to the pattern of the bank portion.

According to various example embodiments, the light emitting elements 310, 410, and 510 may include a blue micro LED configured to emit blue light.

According to various example embodiments, the color conversion layers 330 and 430 may convert the blue light emitted from the blue micro LED into red light or green light.

According to various example embodiments, the light emitting element may include a blue micro LED configured to emit blue light and a green micro LED configured to emit green light, and the color conversion layer corresponding to the blue light may convert the blue light emitted from the blue micro LED into red light.

According to various example embodiments, the display module 160 may include the display panel 210 and the driving circuit 230 configured to generate a driving signal of the plurality of light emitting elements provided in the display panel. The display panel 160 may include the substrate 221, the plurality of light emitting elements 310, 410, and 510 mounted on the substrate, the bank portion 600 disposed on the substrate to space the plurality of light emitting elements apart from each other, the color conversion layers 330 and 430 filled in the cells partitioned by the bank portion to cover the light emitting elements, and the color filter layer 800 covering the bank portion and the color conversion layers. The driving circuit 230 may be disposed on the substrate and be configured to generate the driving signal of the plurality of light emitting elements. In this case, the bank portion 600 may include the first layer 610 having a thickness less than the active layer of the light emitting element, and the second layer 620 laminated (or disposed) on the first layer and spaced apart from the side surface of the light emitting element and configured to reflect the light emitted from the side surface of the light emitting element. In this case, the color filter layer 800 may include the color filters 810 and 820 for different colors, the transmission layer 830, and the black matrix 850 corresponding to the pattern of the bank portion.

According to various example embodiments, the bank portion 600 may further include the third layer 630 laminated (or disposed) on the second layer 620, and the third layer may have a reflectivity higher than the reflectivity of the second layer.

According to various example embodiments, the electronic device 101 may include the display module 160 and the processor 120. The display module 160 may include the display panel 210 including the substrate 221, the plurality of light emitting elements 310, 410, and 510 mounted on the substrate, the bank portion 600 disposed on the substrate to space the plurality of light emitting elements apart from each other, the color conversion layers 330 and 430 filled in the cells partitioned by the bank portion to cover the light emitting elements, and the encapsulation layer 700 covering the bank portion and the color conversion layers, and the driving circuit disposed on the substrate and configured to generate the driving signal of the plurality of light emitting elements. The processor 120 may be configured to control the driving circuit 230 to generate the driving signal for controlling the light emission of the plurality of light emitting elements. In this case, the bank portion 600 may include the first layer 610 which is laminated (or disposed) as at least two layers and having a thickness less than a height of the active layer of the light emitting element, and the second layer 620 disposed on the first layer and spaced apart from the side surface of the light emitting element and configured to reflect the light emitted from the side surface of the light emitting element.

According to various example embodiments, the electronic device 101 may further include the color filter layer 800 covering the bank portion and the color conversion layers. In this case, the color filter layer 800 may include the color filters 810 and 820 for different colors, the transmission layer 830, and the black matrix 850 corresponding to the pattern of the bank portion.

According to various example embodiments, in the electronic device, the first layer of the bank portion may have a reflectivity less than the reflectivity of the second layer 620. In this case, the upper end of the second layer 620 may be at a location higher than a height of the light emitting surface of the light emitting element.

While the disclosure has been illustrated and described with reference to various example embodiments, it will be understood that the various example embodiments are intended to be illustrative, not limiting, and thus the disclosure is not limited to the aforementioned specific embodiments. It will further be understood by those skilled in the art that various modifications can be made, without departing from the true spirit and full scope of the disclosure, including the appended claims and their equivalents. It will also be understood that any of the embodiment(s) described herein may be used in conjunction with any of the other embodiment(s) described herein.

What is claimed is:

1. A display module comprising:
a display panel comprising a substrate, a plurality of light emitting elements mounted on the substrate, a bank portion disposed on the substrate to space the plurality of light emitting elements apart from each other, color conversion layers disposed in cells defined by the bank portion to cover the light emitting elements, and an encapsulation layer covering the bank portion and the color conversion layers; and
a driving circuit disposed on the substrate and configured to generate a driving signal of the plurality of light emitting elements,
wherein the bank portion comprises:
a first layer having a thickness less than a height of an active layer of the light emitting element; and
a second layer disposed on the first layer, spaced apart from a side surface of the light emitting element, and configured to reflect light emitted from the side surface of the light emitting element.

2. The display module according to claim 1, wherein the first layer has a blackish color.

3. The display module according to claim 1, wherein the first layer has a reflectivity less than a reflectivity of the second layer.

4. The display module according to claim 1, wherein the first layer is in close contact with the side surface of the light emitting element.

5. The display module according to claim 1, wherein a width of the first layer is greater than a width of the second layer, and
wherein a region of an upper surface of the first layer is not covered by the second layer.

6. The display module according to claim 1, wherein an upper end of the second layer is at a location higher than a light emitting surface of the light emitting element.

7. The display module according to claim 1, wherein the bank portion further comprises a third layer disposed on the second layer,
wherein the third layer has a blackish color and has a width less than an average width of the second layer, and
wherein the first layer is present in a space between an upper surface of the substrate and a bottom surface of the light emitting element.

8. The display module according to claim 1, wherein the color conversion layer is disposed in a space between the bank portion and a side surface of the light emitting element.

9. The display module according to claim 8, wherein the color conversion layer is disposed in a space between an upper surface of the substrate and a bottom surface of the light emitting element.

10. The display module according to claim 1, further comprising:
a flattening layer disposed on the color conversion layer and comprising a light scattering material,

11. The display module according to claim 1, wherein an upper surface of the flattening layer corresponds to an upper end of the bank portion.

12. The display module according to claim 1, further comprising:
a color filter layer disposed on an upper side of the encapsulation layer,
wherein the color filter layer comprises color filters for different colors, a transmission layer, and a black matrix corresponding to a pattern of the bank portion.

13. The display module according to claim 1, wherein the light emitting element comprises a blue micro light emitting diode (LED) configured to emit blue light, and
wherein the color conversion layer is configured to convert the blue light emitted from the blue micro LED into red light or green light.

14. The display module according to claim 1, wherein the first layer has a light reflectivity or approximately 9% or less.

15. The display module according to claim 1, wherein the second layer has a light reflectivity of approximately 20% or more and an optical density of approximately 1.5 or more.

16. The display module according to claim 7, wherein the third layer has a light reflectivity or approximately 9% or less.

17. The display module according to claim 1, wherein the light emitting element comprises a blue micro light emitting diode (LED) configured to emit blue light and a green micro LED configured to emit green light, and
wherein the color conversion layer corresponding to the red light is configured to convert the blue light emitted from the blue micro LED into red light.

18. A display module comprising:
a display panel comprising a substrate, a plurality of light emitting elements mounted on the substrate, a bank portion disposed on the substrate to space the plurality of light emitting elements apart from each other, color conversion layers disposed in cells defined by the bank portion to cover the light emitting elements, and a color filter layer covering the bank portion and the color conversion layers; and
a driving circuit disposed on the substrate and configured to generate a driving signal of the plurality of light emitting elements,
wherein the bank portion comprises:
a first layer having a thickness less than a height of an active layer of the light emitting element and having a blackish color;
a second layer disposed on the first layer, spaced apart from a side surface of the light emitting element, and configured to reflect light emitted from the side surface of the light emitting element; and
a third layer disposed on the second layer,
wherein the color filter layer comprises color filters for different colors, a transmission layer, and a black matrix corresponding to a pattern of the bank portion, and
wherein the first layer has a reflectivity less than a reflectivity of the second layer and the third layer has a reflectivity greater than the reflectivity of the second layer.

19. An electronic device comprising:
a display module comprising a display panel comprising a substrate, a plurality of light emitting elements mounted on the substrate, a bank portion disposed on the substrate to space the plurality of light emitting elements apart from each other, color conversion layers disposed in cells defined by the bank portion to cover the light emitting elements, an encapsulation layer covering the bank portion and the color conversion layers, and a driving circuit disposed on the substrate and configured to generate a driving signal of the plurality of light emitting elements; and
a processor configured to control the driving circuit to generate a driving signal for controlling light emission of the plurality of light emitting elements,
wherein the bank portion comprises at least two layers including:
a first layer having a thickness less than a height of an active layer of the light emitting element; and
a second layer disposed on the first layer, spaced apart from a side surface of the light emitting element, and configured to reflect light emitted from the side surface of the light emitting element, and
wherein the first layer has a reflectivity less than a reflectivity of the second layer.

20. The electronic device according to claim 19, further comprising:
a color filter layer covering the bank portion and the color conversion layers,
wherein the color filter layer comprises color filters for different colors, a transmission layer, and a black matrix corresponding to a pattern of the bank portion, and
wherein an upper end of the second layer is at a location higher than a light emitting surface of the light emitting element.
